(19) United States
(12) Patent Application Publication
(10) Pub. No.: US 2005/0051842 A1
(43) Pub. Date: Mar. 10, 2005

(54) Apparatus and a manufacturing method of a thin-film transistor LCD

(76) Inventors: Meng-Chi Liou, Taoyuan City (TW); Yang-Hui Chang, Sinpu Township (TW); Kuang-Hsiang Lin, Gueishan Township (TW)

Correspondence Address: BIRCH STEWART KOLASCH & BIRCH, PO BOX 747, FALLS CHURCH, VA, 22040-0747, US

(21) Appl. No.: 10/654,436

(22) Filed: Sep. 4, 2003

(51) Int. Cl. H01L 21/00; H01L 21/84; H01L 27/01; H01L 31/0392

(52) U.S. Cl. 257/347; 438/151

(57) ABSTRACT

A thin-film transistor (hereinafter referred to as “TFT”) LCD (liquid crystal display) apparatus and its manufacturing method can improve the shortages of improper metal coating protection and incomplete light shielding. Besides, the semi-conductor layer usually uses A-Si layer as a light shielding and a coating materials. Furthermore, the TFT-LCD apparatus and its manufacturing method of the present invention can effectively overcome incomplete light shielding problem of the prior art without using extra numbers of masks for achieving the anti-electrostatic purpose.

### BACKGROUND OF THE INVENTION

1. Filed of the Invention

The present invention relates to a TFT-LCD apparatus. More particularly, it means a TFT-LCD apparatus with a semiconductor passivation layer. By using a TFT-LCD apparatus of the present invention can effectively overcome the incomplete light-shielding problem and further achieve the anti-electrostatic purpose.

2. Description of the Related Art

In the traditional TFT-LCD apparatus, the residual stress is formed after completing panel cutting manufacturing process. This makes insulating layer easily occur defects in the gate electrode layer of a TFT-LCD apparatus. Furthermore, the water vapor in the air etches into the panel, therefore, the gate driver IC inputs signals into the voltage of the wires and causes metal wiring etching phenomenon. Especially, the input voltage is higher in the gate electrode and the metal wiring oxidation problem is occurred while using a gate electrode wire with AlNd.

Referring to FIG. 1a, it is a cross-sectional view showing a gate electrode according to a prior art. The metal wires of the gate electrode (21a, 21b, 21c, and 21d) of the traditional TFT-LCD apparatus are placed on the thin-film transistor substrate (10). Further, the metal wires (21a, 21b, 21c, and 21d) of said gate electrode is without any passivation layers. As a result, the cross-section of the metal layer (20) is easily to occur defects (22) while processing next manufacturing or packaging process.

Further, according to FIG. 1b, is a cross-sectional view showing a gate electrode with a metal passivation layer structure according to a prior art. In traditional TFT-LCD apparatus, a thin-film transistor substrate (10) is at least with a metal layer (20). More particularly, the wet etching is to produce multiple metal passivation layers (23a, 23b, 23c, and 23d). The said multiple metal passivation layers (23a, 23b, 23c, and 23d) can protect gate electrode wires in order to avoid defects from occurring. Next, please refer to FIG. 1c, it is a cross-sectional view showing a source electrode with a gate electrode passivation according to a prior art. The said multiple metal layers can be source electrode metal passivation layer (23). However, the width of the structure in said multiple metal passivation layers (23a, 23b, 23c, and 23d) is difficult to control, and causes wiring short-cut problems happen. In addition, the coating method of said multiple metal passivation layers (23a, 23b, 23c, and 23d) enhances the wiring width become narrower, therefore, easily causes signal coupling problems as well as improper display.

Accordingly, the present invention uses a semiconductor layer to alternate the traditional metal passivation structure. The said semiconductor layer structure can have a light shielding and an anti-electrostatic protection in a TFT-LCD apparatus. Further, the present invention can effectively overcome wiring etching problems without using extra numbers of masks.

In addition, in order to conduct liquid crystal into the manufacturing process in a general TFT-LCD apparatus, BM (black matrix) has to be removed from the color filter substrate (30). Then, terminals in wiring area will be found while turning the light of the panel, especially the light leakage problem is occurred in the source electrode. Please referring to FIG. 2a, it is a cross-sectional view showing a source electrode according to a prior art. The source electrode side has a color filter substrate (30), and the said substrate (30) further has a metal layer (40) including multiple source electrode metal wires (41a, 41b, 41c, and 41d). While the said color filter substrate (30) and multiple source electrode metal wires (41a, 41b, 41c, and 41d) without any passivation layers, the light-emitting problem is easily happened. This is the reason why traditional TFT-LCD apparatus has a light leakage problem. FIG. 2b is the traditional solution to overcome the problem. As shown in FIG. 2b, it is a cross-sectional view showing a source electrode with metal passivation layer structure according to a prior art. The GE metal passivation layer adds into source electrode metal as a light shielding solution. In other words, it is a structure with multiple metal passivation layers (42a, 42b, 42c). Please referring to FIG. 2c, it is a cross-sectional view showing a gate electrode with light shielding structure of a source electrode according to a prior art. The said metal passivation layers can be a electrode metal passivation layer (42), however, the metal wiring width of the metal passivation layers is difficult to control as taking this solution. Furthermore, incomplete light shielding and wiring shortcut is easily happened. More, unnecessary noise and interference will occur in the signal coupling process. From above description, the present invention uses a semiconductor layer to alternate the metal passivation structure as light shielding and coating materials. More, it can further solve incomplete light shielding problems in source electrode without using extra manufacturing processes and mask numbers.

### SUMMARY OF THE INVENTION

The main purpose of he present invention is to provide a thin-film transistor LCD (Light Crystal Display) apparatus. More particularly, it is a TFT-LCD apparatus comprising semiconductor layers. By using the semiconductor layer structure, it can overcome the light leakage problem of a TFT-LCD apparatus for achieving an effective light shielding purpose.

Another purpose of the present invention is to provide a TFT-LCD apparatus with an anti-electrostatic function. By using a semi-conductor layer structure, it can overcome signal-coupling problems between connecting wires for effectively achieving anti-electrostatic purpose.

Providing a TFT-LCD manufacturing method is another purpose of the present invention. More particularly, it relates to a TFT-LCD manufacturing method with a semi-conductor layer. By using this manufacturing method, it can include a semiconductor layer of TFT-LCD apparatus and the said semiconductor layer can effectively cover on the TFT-LCD apparatus for achieving an anti-electrostatic and light shielding purposes.

There are just some of the features and advantages of the present invention. Many others will apparent by reference to the detailed description of the invention taken in combination with the accompanying drawings.

### BRIEF DESCRIPTION OF DRAWINGS

FIG. 1a is a cross-sectional view showing a gate electrode according to a prior art;

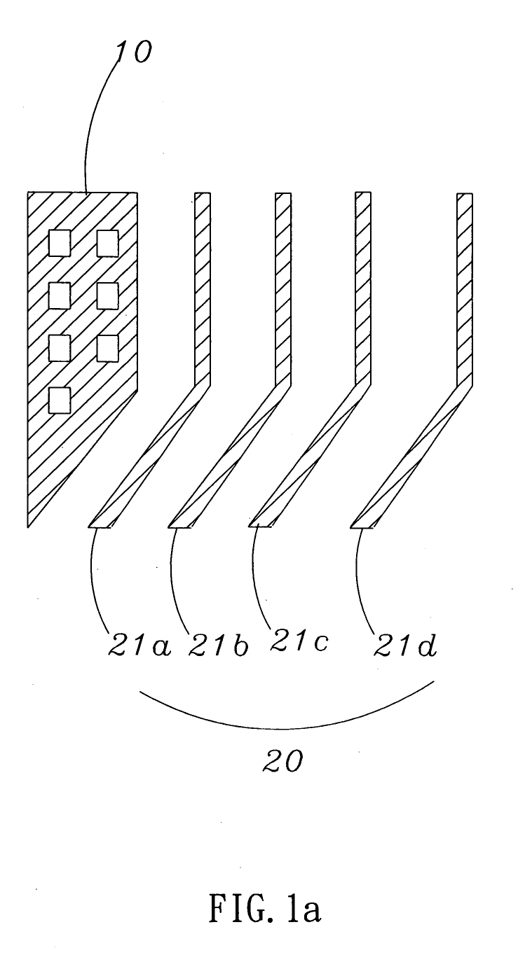

FIG. 1b is a cross-sectional view showing a gate electrode with a metal passivation layer structure according to a prior art;

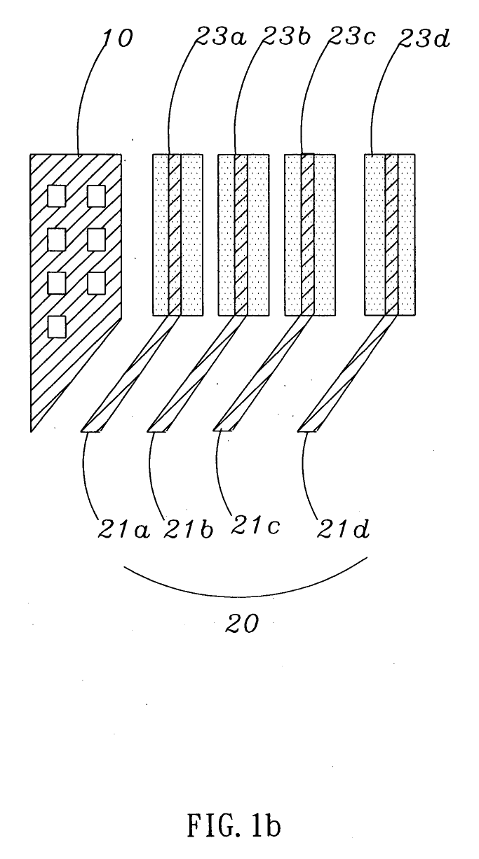

FIG. 1c is a cross-sectional view showing a source electrode with a gate electrode passivation according to a prior art;

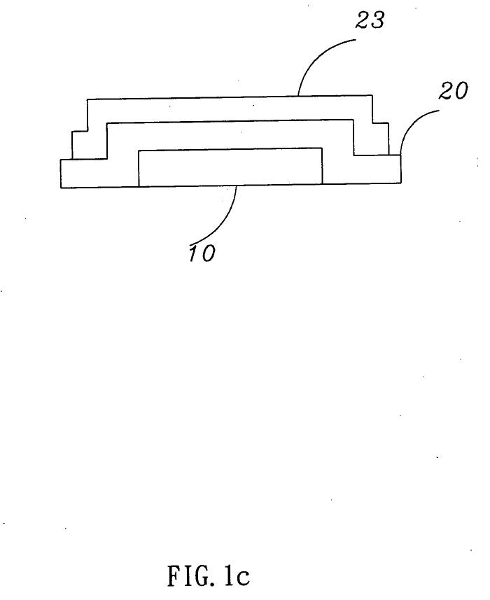

FIG. 2a is a cross-sectional view showing a source electrode according to a prior art;

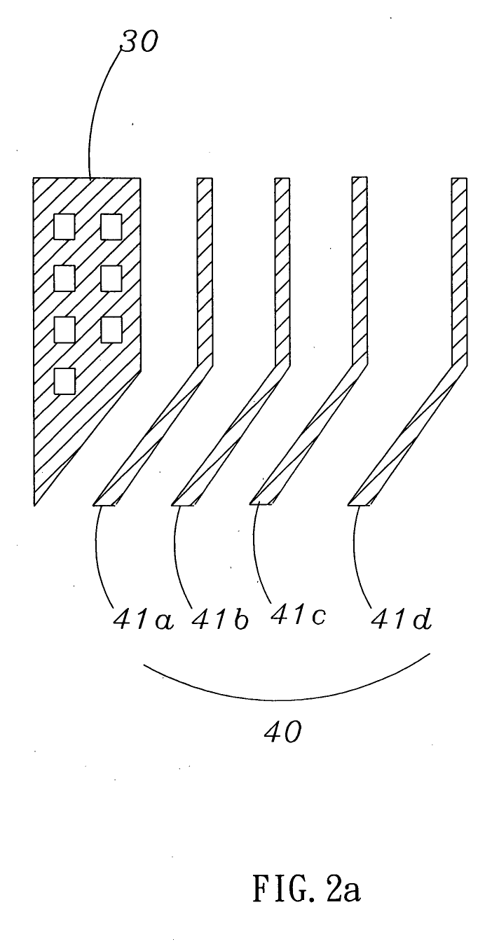

FIG. 2b is a cross-sectional view showing a source electrode with metal passivation layer structure according to a prior art;

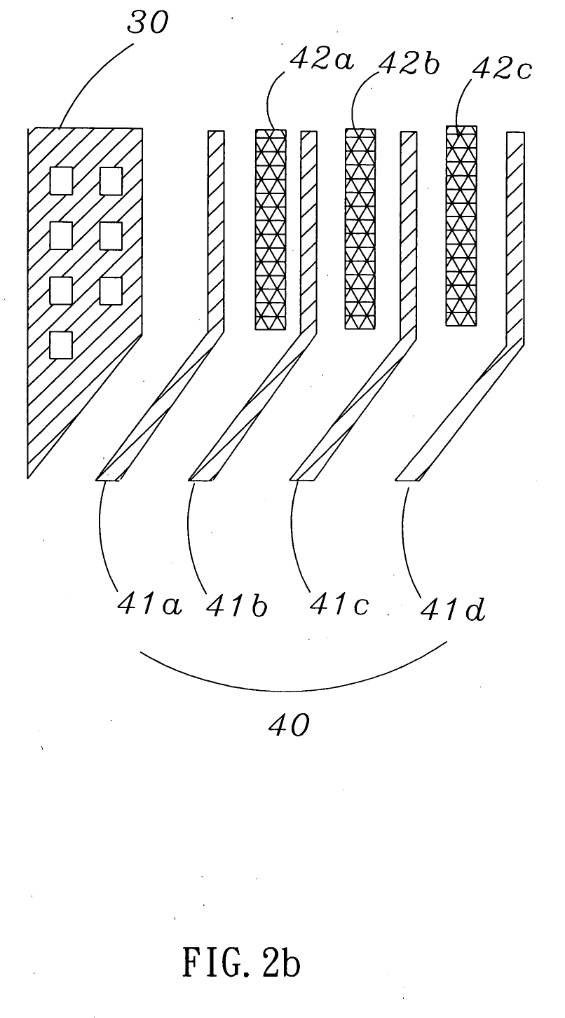

FIG. 2c is a cross-sectional view showing a gate electrode with light shielding structure of a source electrode according to a prior art;

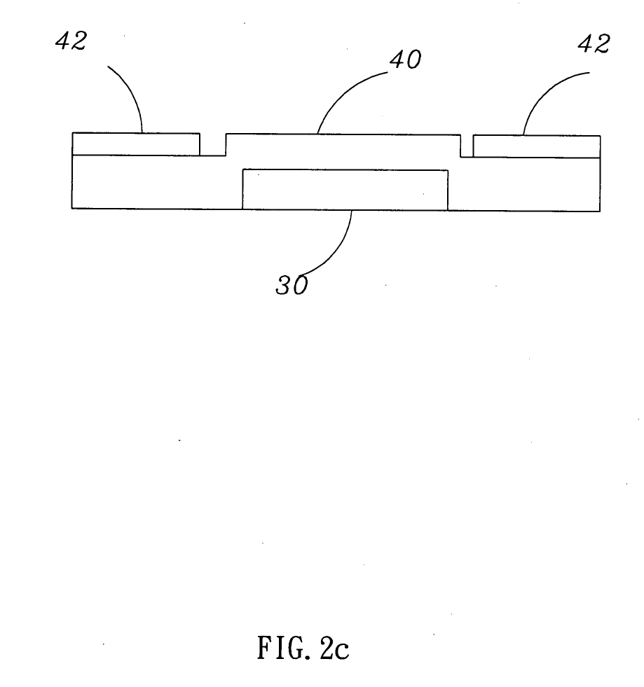

FIG. 3a is a cross-sectional view showing a gate electrode fully covered with a semiconductor layer structure according to the present invention;

FIG. 3b is a cross-sectional view showing a gate electrode with the semiconductor layer passivation according to the present invention;

FIG. 4a is a cross-sectional view showing a source electrode with light shielding protection of a semiconductor layer structure according to the present invention; and

FIG. 4b is a cross-sectional view showing a source electrode fully covered with a semiconductor layer structure according to the present invention.

### DETAILED DESCRIPTION OF THE PREFERRED EMBODIEMENTS

The present invention relates to a TFT-LCD apparatus, which includes a substrate and the said substrate situated on the bottom side of the TFT-LCD apparatus. A first metal layer on the said substrate as a GE wire in the TFT-LCD apparatus is also included. Further, A semiconductor layer on the said first metal layer as an active layer in the apparatus is included. More, a second metal layer as a source electrode wire for effectively achieving back-light shielding and providing an anti-electrostatic protection is also included.

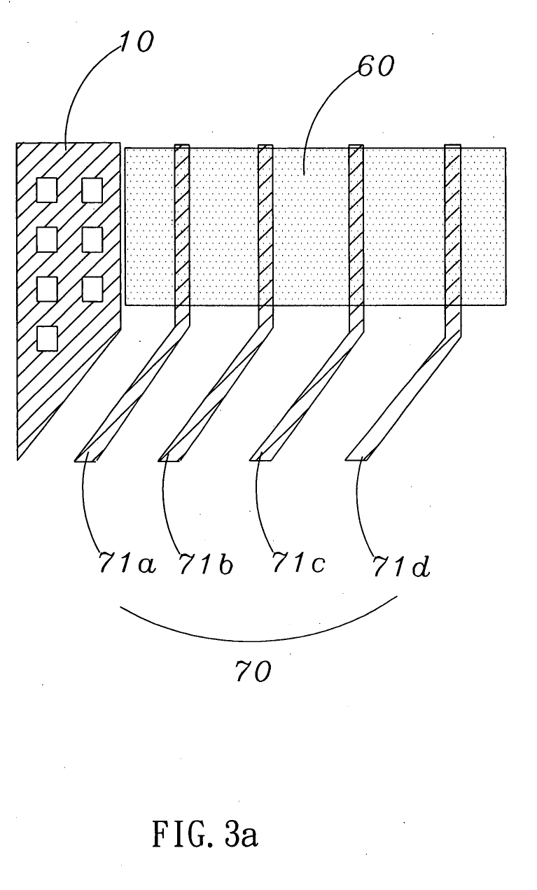

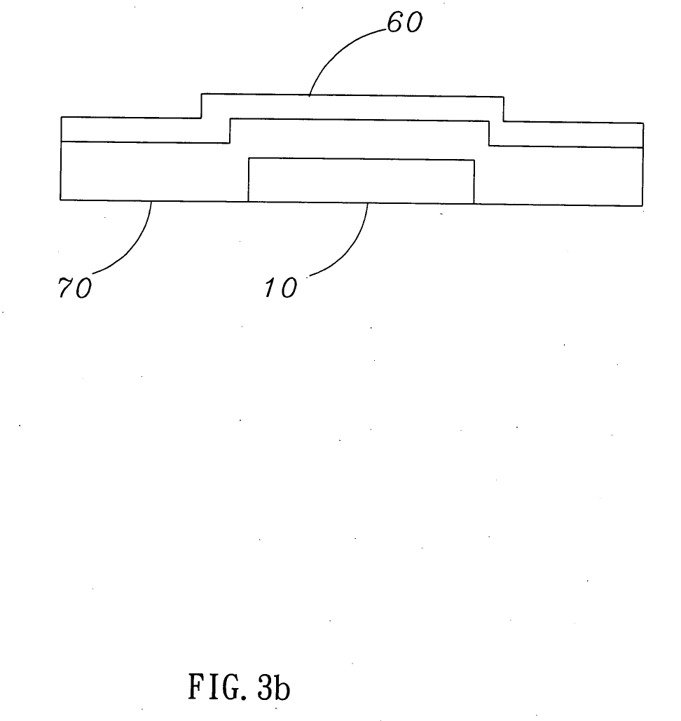

Next, as shown in FIG. 3a, it is a cross-sectional view showing a gate electrode fully covered with a semiconductor layer structure according to the present invention. The said TFT-LCD apparatus includes a TFT substrate (10), and the top of the said TFT substrate (10) has at least one metal layer (80). The said metal layer (80) has multiple metal wires (81a, 81b, 81c, and 81d) situated on the top side of the said TFT substrate (10). At least one semiconductor layer is included here. The said semiconductor layer (60) can be composed of A-Si, Poly-Si, or GeSi Alloy material, and floatingly connected with the said GE metal layer (70), but not electrically connected with the said metal wires (71a, 71b, 71c, and 71d). Please referring to FIG. 3b, it is a cross-sectional view showing a gate electrode with the semiconductor layer passivation according to the present invention. The said semiconductor layer (60) is a striped shape covering on the GE metal wires (71a, 71b, 71c, and 71d). Further, it can effectively overcome defects occurring in the gate electrode of a TFT-LCD apparatus, and provide an anti-electrostatic protection.

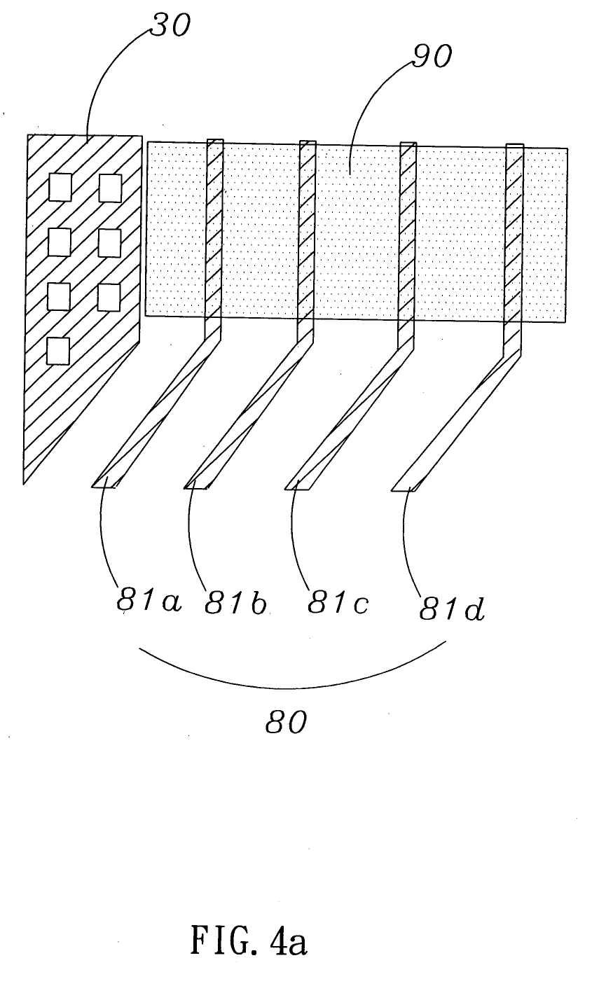

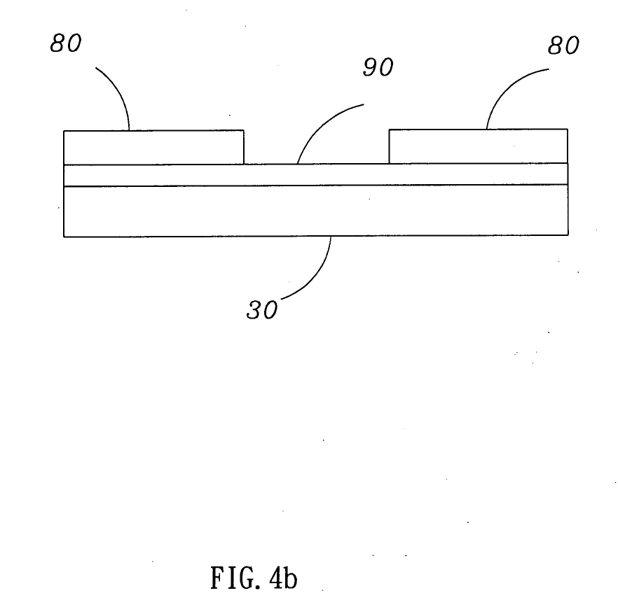

Referring to FIG. 4a, it is a cross-sectional view showing a source electrode with light shielding protection of a semiconductor layer structure according to the present invention. The width of the said striped-shape semiconductor layer (90) in a TFT-LCD apparatus can be wider than the width of the said source electrode metal wires (81a, 81b, 81c, and 81d). More, it can effectively overcome light leakage problem in the source electrode of a TFT-LCD apparatus. Furthermore, FIG. 4b is a cross-sectional view showing a source electrode fully covered with a semiconductor layer structure according to the present invention. The said metal layer (80) of the present invention includes multiple metal wires (81a, 81b, 81c, and 81d) for a source electrode wire of the said TFT-LCD apparatus. The said semiconductor layer (90) here can be composed of A-Si, Poly-Si, or GeSi Alloy material. By using source electrode metal layer (80) fully covered with the said semiconductor layer (80), the said color filter substrate (30) can achieve light shielding in source electrode.

Another preferred embodiment of the present invention is with a fully covered semiconductor layer structure. The said semiconductor layer can be an active layer as well as a meshed structure of large area in the said TFT-LCD apparatus. Further, the said semiconductor layer covers on either down side or up side metal wires of the said metal layer.

Next, the present invention further comprises a TFT-LCD manufacturing method, which applies to a TFT-LCD. The following steps are included; Firstly, forming a first metal layer on the substrate, defining a first metal wire, and then forming an insulating layer on it. Secondly, forming a first semiconductor layer on a said first metal layer. Thirdly, forming a second semiconductor layer on a said first semiconductor layer. Fourthly, forming a second metal layer on a said second semiconductor layer, and defining a second metal wire. The substrate herein can be a color filter substrate or a TFT substrate. The said first metal layer forms a gate electrode on a said TFT substrate. The said second metal layer forms a source electrode on a said color filter substrate. By suing a said semiconductor layer, it can effectively shield the back-light in gate electrode layer and source electrode layer. More, it can provide an anti-electrostatic protection.

In conclusion, the present invention meets novelty, improvement, and is applicable to the industry. It therefore meets the essential elements in patentability. There is no doubt that the present invention is legal to apply to the patent, and indeed we hope that this application can be granted as a patent.

While the invention has been described in terms of what are presently considered to be the most practical and preferred embodiments, it is to be understood that the invention needs not be limited to the disclosed embodiment. On the contrary, it is intended to cover various modifications and similar arrangements included within the spirit and scope of the appended claims while which are to be accord with the broadest interpretation so as to encompass all such modifications and similar structures.

1. A Thin-Film Transistor (TFT)—Liquid Crystal Display (LCD) apparatus, at least comprising;
a substrate;
a metal layer having multiple metal wires, connected with the upper side of the substrate; and
a semiconductor layer having a floating connection with said metal layer, but without having an electricity connection with said metal layer;
wherein said semiconductor layer can effectively provide light-shielding and anti-electrostatic protections.

2. The TFT-LCD apparatus according to claim 1, wherein said substrate can be Thin-Film Transistor (TFT) substrate.

3. The TFT-LCD apparatus according to claim 1, wherein said substrate can be color filter substrate.

4. The TFT-LCD apparatus according to claim 2, wherein said metal layer can be a gate electrode wire in TFT-LCD apparatus.

5. The TFT-LCD apparatus according to claim 3, wherein said metal layer can be a source electrode wire in TFT-LCD apparatus.

6. The TFT-LCD apparatus according to claim 1, wherein said semiconductor layer can be an active layer in TFT-LCD apparatus.

7. The TFT-LCD apparatus according to claim 1, wherein said semiconductor layer can be a meshed coating covering on the down side of the said multiple metal wires.

8. The TFT-LCD apparatus according to claim 1, wherein said semiconductor layer can be a striped shape situated between said multiple metal wires.

9. A TFT-LCD apparatus according to claim 1, wherein said semiconductor layer can be a striped shape covering on said multiple metal wires.

10. The TFT-LCD apparatus according to claim 1, wherein said semiconductor layer can be a meshed coating covering on the said multiple metal wires.

11. The TFT-LCD apparatus according to claim 1, wherein said semiconductor layer can be composed of A-Si layer materials.

12. The TFT-LCD apparatus according to claim 1, wherein said semiconductor layer can be composed of Poly-Si layer materials.

13. The TFT-LCD apparatus according to claim 1, wherein said semiconductor layer can be composed of SiGe Alloy layer materials.

14. The TFT-LCD apparatus according to claim, wherein the width of said striped shape semiconductor layer can be wider than the width of said metal wires.

15. The Thin-Film Transistor (TFT)—Liquid Crystal Display (LCD) manufacturing method applies to a TFT-LCD, comprising the steps of:
forming a first metal layer on said substrate, and defining a first metal layer wire;
forming a first semiconductor layer on said first metal layer;
forming a second semiconductor layer on said first semiconductor layer;
forming a second metal layer on said second semiconductor layer, and defining a second metal wire;
wherein said substrate can be a color filter substrate or a TFT substrate. The said first metal layer and the said second metal layer are on the said TFT substrate forming gate electrode wires, further, the said first metal layer and the said second metal layer are on the color filter substrate forming source electrode wires, and by using said semiconductor layer can effectively achieve back-light shielding and provide an anti-electrostatic protection.

16. The TFT-LCD manufacturing method according to claim 15, wherein said metal layer can be a gate electrode wire in TFT-LCD apparatus.

17. The TFT-LCD manufacturing method according to claim 15, wherein said metal layer can be a source electrode wire in TFT-LCD apparatus.

18. The TFT-LCD manufacturing method according to claim 15, wherein said semiconductor layer can be a striped shape situated between said metal wires in said metal layer.

19. The TFT-LCD manufacturing method according to claim 15, wherein said semiconductor layer can be a meshed coating covering on the said metal wires in said metal layer.
